(19) United States
(12) Patent Application Publication
(10) Pub. No.: US 2026/0033265 A1
(43) Pub. Date: Jan. 29, 2026

(54) ETCHING METHOD AND PLASMA PROCESSING APPARATUS

(71) Applicant: Tokyo Electron Limited, Tokyo (JP)

(72) Inventors: Noriyoshi ARIMA, Miyagi (JP); Yoshihide KIHARA, Miyagi (JP); Maju TOMURA, Miyagi (JP); Kae TAKAHASHI, Miyagi (JP)

(73) Assignee: Tokyo Electron Limited, Tokyo (JP)

(21) Appl. No.: 19/350,098

(22) Filed: Oct. 6, 2025

Related U.S. Application Data
(63) Continuation of application No. PCT/JP2024/007472, filed on Feb. 29, 2024.

(30) Foreign Application Priority Data
Apr. 13, 2023 (JP) 2023-065637

(51) Int. Cl. H01L 21/311; H01J 37/32

(52) U.S. Cl. CPC H01L 21/31144; H01J 37/32724; H01L 21/31116; H01J 2237/332; H01J 2237/334

(57) ABSTRACT

An etching method is provided. This method includes (a) preparing a substrate, the substrate including an etching target film and a mask including an opening disposed on the etching target film, the etching target film including a recessed portion, and the mask configured to expose the recessed portion and; (b) forming a metal-containing film on a side wall of the recessed portion using a first plasma formed from a first processing gas including a metal-containing gas, the metal-containing gas including at least one metal selected from a group comprising ruthenium, tungsten, molybdenum, and titanium; and (c) etching the etching target film in the recessed portion using a second plasma formed from a second processing gas including a hydrogen fluoride gas.

### CROSS-REFERENCE TO RELATED APPLICATIONS

The present application claims priority under 35 U.S.C. § 119 to PCT No. PCT/JP2024/007472, filed on Feb. 29, 2024, and Japanese Patent Application No. 2023-065637 filed on Apr. 13, 2023, the entire contents of each of which are incorporated herein by reference.

### BACKGROUND

### Field

An exemplary embodiment of the present disclosure relates to an etching method and a plasma processing apparatus.

### Description of Related Art

JP2016-21546A discloses a technique for etching a silicon-containing film while suppressing bowing.

### SUMMARY

In one exemplary embodiment of the present disclosure, there is provided an etching method: (a) preparing a substrate, the substrate including an etching target film and a mask disposed on the etching target film, the etching target film including a recessed portion, and the mask including an opening configured to expose the recessed portion; (b) forming a metal-containing film on a side wall of the recessed portion using a first plasma formed from a first processing gas, the first processing gas including a metal-containing gas, and the metal-containing gas including at least one metal selected from a group comprising ruthenium, tungsten, molybdenum, and titanium; and (c) etching the etching target film in the recessed portion using a second plasma formed from a second processing gas, the second processing gas including a hydrogen fluoride gas.

### BRIEF DESCRIPTION OF DRAWINGS

FIG. 1 is a diagram for describing a configuration example of a plasma processing apparatus.

FIG. 2 is a diagram for describing a configuration example of a capacitively coupled plasma processing apparatus.

FIG. 3 is a diagram for describing an example of bowing.

FIG. 4 is a flowchart illustrating an example of the present method.

FIG. 5 is a diagram illustrating an example of a cross-sectional structure of a substrate W provided in step ST11.

FIG. 6 is a diagram illustrating an example of the cross-sectional structure of the substrate W after processing of step ST12.

FIG. 7 is a diagram illustrating an example of the cross-sectional structure of the substrate W after processing of step ST2.

FIG. 8 is a diagram illustrating an example of the cross-sectional structure of the substrate W during processing of step ST3.

### DETAILED DESCRIPTION

Hereinafter, each embodiment of the present disclosure will be described.

In one exemplary embodiment, there is provided an etching method including: (a) preparing a substrate, the substrate including an etching target film and a mask disposed on the etching target film, the etching target film including a recessed portion, and the mask including an opening configured to expose the recessed portion; (b) forming a metal-containing film on a side wall of the recessed portion using a first plasma formed from a first processing gas, the first processing gas including a metal-containing gas, and the metal-containing gas including at least one metal selected from the group comprising ruthenium, tungsten, molybdenum, and titanium; and (c) etching the etching target film in the recessed portion using a second plasma formed from a second processing gas, the second processing gas including a hydrogen fluoride gas.

In one exemplary embodiment, the second processing gas further includes the metal-containing gas, and in the (c), the metal-containing film is formed on the side wall of the recessed portion, and the etching target film is etched in the recessed portion.

In one exemplary embodiment, a cycle including the (b) and the (c) is repeated a plurality of times.

In one exemplary embodiment, the second processing gas further includes a phosphorus-containing gas.

In one exemplary embodiment, in the (c), a temperature of the substrate or a substrate support configured to support the substrate is controlled to 0° C. or lower.

In one exemplary embodiment, there is provided an etching method including: (a) preparing a substrate, the substrate including an etching target film and a mask disposed on the etching target film, the etching target film including a recessed portion, and the mask including an opening configured to expose the recessed portion; and (b) forming a metal-containing film on a side wall of the recessed portion using a plasma formed from a processing gas, and etching the etching target film in the recessed portion, the processing gas including a metal-containing gas and a hydrogen fluoride gas, and the metal-containing gas including at least one metal selected from the group consisting of ruthenium, tungsten, molybdenum, and titanium or at least one metal selected from the group comprising ruthenium, tungsten, molybdenum, and titanium.

In one exemplary embodiment, the processing gas further includes a phosphorus-containing gas.

In one exemplary embodiment, in the (b), a temperature of the substrate or a substrate support configured to support the substrate is controlled to 0° C. or lower.

In one exemplary embodiment, the etching target film is a silicon-containing film, a carbon-containing film, or a metal oxide film.

In one exemplary embodiment, the etching target film includes at least one selected from the group consisting of a silicon oxide film, a silicon nitride film, a silicon oxynitride film, a silicon carbonitride film, a polycrystalline silicon film, and a film stack including at least two of these films or at least one selected from the group comprising a silicon oxide film, a silicon nitride film, a silicon oxynitride film, a silicon carbonitride film, a polycrystalline silicon film, and a film stack including at least two of these films.

In one exemplary embodiment, the mask includes at least one metal selected from the group consisting of ruthenium, tungsten, molybdenum, titanium, indium, gallium, and zinc or at least one metal selected from the group comprising ruthenium, tungsten, molybdenum, titanium, indium, gallium, and zinc.

In one exemplary embodiment, the mask is a carbon-containing film.

In one exemplary embodiment, the substrate includes an etching stop film under the etching target film, and the etching stop film includes at least one metal selected from the group consisting of ruthenium, tungsten, molybdenum, titanium, indium, gallium, and zinc or at least one metal selected from the group comprising ruthenium, tungsten, molybdenum, titanium, indium, gallium, and zinc.

In an exemplary embodiment, a plasma processing apparatus including: a chamber; and a controller, in which the controller is configured to perform (a) a control of preparing a substrate in the chamber, the substrate including an etching target film and a mask disposed on the etching target film, the etching target film including a recessed portion, and the mask including an opening configured to expose the recessed portion, (b) forming of a metal-containing film on a side wall of the recessed portion using a first plasma formed from a first processing gas in the chamber, the first processing gas including a metal-containing gas, the metal-containing gas including at least one metal selected from the group consisting of ruthenium, tungsten, molybdenum, and titanium or at least one selected from the group comprising ruthenium, tungsten, molybdenum, and titanium; and (c) etching of the etching target film in the recessed portion using a second plasma formed from a second processing gas in the chamber, the second processing gas including a hydrogen fluoride gas.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Configuration Example of Plasma Processing System

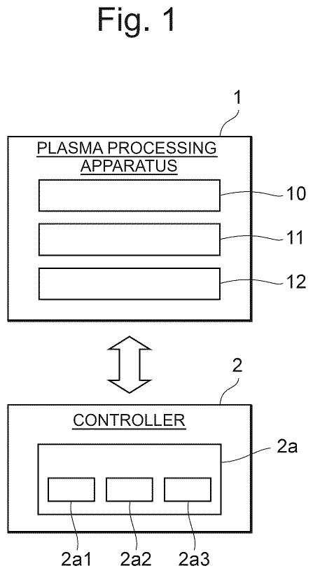

FIG. 1 is a diagram for describing a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20, described later, and the gas exhaust port is connected to an exhaust system 40 described later. The substrate support 11 is disposed in the plasma processing space and has a substrate support surface for supporting a substrate.

The plasma generator 12 is configured to form a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. In addition, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction(s) that causes the plasma processing apparatus 1 to execute various steps described in the present disclosure. The controller 2 may be configured to control each element of the plasma processing apparatus 1 such that the various steps described here are executed. In an embodiment, a part or the entirety of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and execute the read out program such that various control operations are performed. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

### Configuration Example of Capacitively Coupled Plasma Processing Apparatus

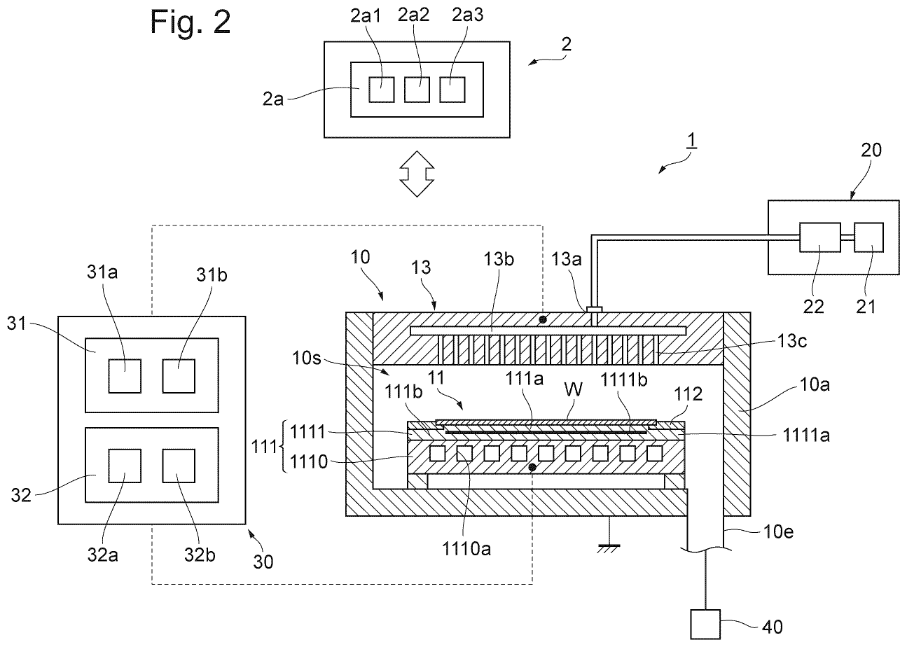

Hereinafter, a configuration example of the capacitively coupled plasma processing apparatus as an example of the plasma processing apparatus 1 will be described. FIG. 2 is a diagram for describing a configuration example of the capacitively coupled plasma processing apparatus.

The capacitively coupled plasma processing apparatus 1 includes the plasma processing chamber 10, the gas supply 20, a power supply 30, and the exhaust system 40. In addition, the plasma processing apparatus 1 includes the substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 such that the substrate W on the center region 111a of the main body 111 is surrounded. Therefore, the center region 111a is also referred to as a substrate support surface for supporting the substrate W, and the annular region 111b is also referred to as an edge ring support surface for supporting the ring assembly 112.

In an embodiment, the main body 111 includes a base 1110 and an electrostatic chuck 1111. The base 1110 includes a conductive member and may be a conductive base. The conductive member of the base 1110 may function as a lower electrode. The electrostatic chuck 1111 is disposed on the base 1110. The electrostatic chuck 1111 includes a ceramic member 1111a and an electrostatic electrode (chuck electrode) 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. In a case where a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Therefore, the substrate support 11 includes at least one lower electrode.

The ring assembly 112 includes one or more annular members. In an embodiment, one or more annular members include one or more edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or more heaters are disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or more side gas injectors (SGI) attached to one or more opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma can be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in the range of 10 MHz to 150 MHz. In an embodiment, the first RF generator 31a may be configured to generate a plurality of source RF signals having different frequencies. The generated one or more source RF signals are supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in a range of 100 kHz to 60 MHz. In an embodiment, the second RF generator 31b may be configured to generate a plurality of bias RF signals having different frequencies. The generated one or more bias RF signals are supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In an embodiment, the first DC generator 32a is connected to at least one lower electrode, and is configured to generate the first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses based on DC is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or more voltage pulses of a positive polarity and one or more voltage pulses of a negative polarity in one cycle. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### Example of Bowing

Bowing is known as one of the shape abnormalities in plasma etching. The bowing is a phenomenon in which an opening dimension of a part of a side wall of a recessed portion formed by etching is larger than an opening dimension of a top portion of the recessed portion. The portion where the bowing occurs has, for example, a barrel-like shape in cross-sectional view. It is considered that the bowing may occur due to scraping of a part of the side wall of the recessed portion by ions or the like rebounded by a mask or the like.

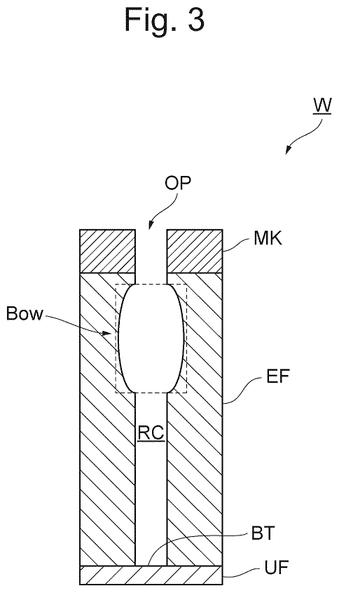

FIG. 3 is a diagram for describing an example of bowing. FIG. 3 is an example of a cross-sectional structure in a case where an etching target film EF of the substrate W is etched via a mask MK having an opening OP to form a recessed portion RC. In this example, a bowing Bow having a barrel shape in a cross-sectional view is generated on an upper side (low aspect region) of the recessed portion RC in a state where a bottom portion BT of the recessed portion RC reaches an underlying film UF. An opening dimension of the recessed portion RC in which the bowing bow occurs is larger than an opening dimension of a middle to lower side (middle aspect region to high aspect region) of the recessed portion RC. The bowing may occur not only on the upper side of the recessed portion RC but also on the middle to lower side of the recessed portion RC.

An etching method (hereinafter, referred to as “the present method”) according to one exemplary embodiment of the present disclosure may suppress such bowing. Hereinafter, the description will be made with reference to the drawings.

### Example of Present Method

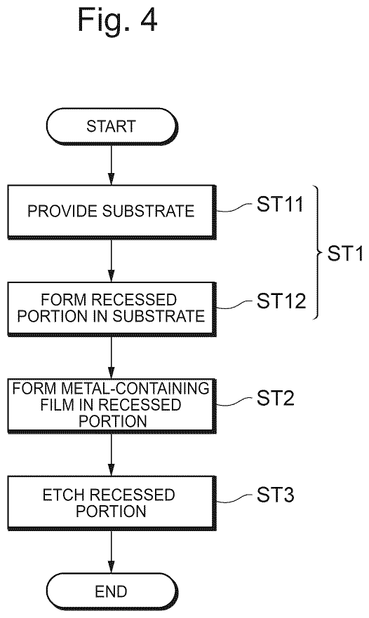

FIG. 4 is a flowchart illustrating an example of the present method. The present method includes step ST1 of preparing the substrate, step ST2 of forming a metal-containing film on the recessed portion, and step ST3 of etching the recessed portion. Step ST1 includes step ST11 of providing the substrate W and step ST12 of etching the substrate W to form the recessed portion. In an embodiment, the processing in each step may be executed by the plasma processing apparatus 1 (see FIGS. 1 and 2). In the following example, the controller 2 controls each unit of the capacitively coupled plasma processing apparatus 1 (see FIG. 2) to execute the present method.

### Step ST1: Preparation of Substrate

In step ST1, the substrate including the recessed portion is prepared. First, in step ST11, the substrate W is provided in the plasma processing space 10s of the plasma processing apparatus 1. Then, in step ST12, the recessed portion is formed in the substrate W.

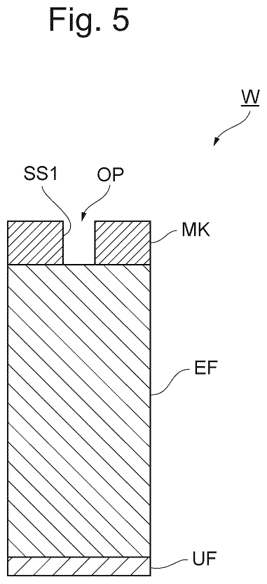

In step ST11, the substrate W is disposed in the center region 111a of the substrate support 11 and is held in the substrate support 11 by the electrostatic chuck 1111. FIG. 5 is a diagram illustrating an example of a cross-sectional structure of the substrate W provided in step ST11. As illustrated in FIG. 5, the substrate W includes the etching target film EF and the mask MK disposed on the etching target film EF. In an embodiment, the etching target film EF may be formed on the underlying film UF. The substrate W may be used for manufacturing a semiconductor device. For example, the semiconductor device includes a semiconductor memory device such as a DRAM and a 3D-NAND flash memory.

In an embodiment, the underlying film UF is a silicon wafer, an organic film, a dielectric film, a metal film, a semiconductor film, or the like formed on the silicon wafer. In an embodiment, the underlying film UF may include an etching stop film. In an embodiment, the etching stop film contains at least one metal selected from the group consisting of tungsten, molybdenum, ruthenium, titanium, indium, gallium, and zinc or at least one metal selected from the group comprising tungsten, molybdenum, ruthenium, titanium, indium, gallium, and zinc. The etching stop film may contain, for example, a carbide or a silicide of the above-described metal. The etching stop film may be, for example, a tungsten-containing film. The etching stop film may further include tungsten and at least one selected from the group consisting of silicon, carbon, and nitrogen or at least one selected from the group comprising silicon, carbon, and nitrogen. In an example, the etching stop film contains at least one selected from the group consisting of tungsten carbide, tungsten silicide, WSiN, and WSiC or at least one selected from the group comprising tungsten carbide, tungsten silicide, WSiN, and WSiC. The etching stop film may contain, for example, at least one selected from the group consisting of ruthenium, tungsten silicide, titanium nitride, molybdenum, and InGaZnO or the group comprising ruthenium, tungsten silicide, titanium nitride, molybdenum, and InGaZnO.

In an embodiment, the underlying film UF may be configured by stacking a plurality of films. In a case where the underlying film UF is configured of a plurality of films, the etching stop film may be formed on the uppermost layer of the underlying film UF. That is, the etching stop film may be disposed to be in contact with the etching target film EF.

The etching target film EF is a film which is a target of etching by the present method. The etching target film EF may be configured by one film or may be configured by stacking a plurality of films.

In an embodiment, the etching target film EF is a silicon-containing film. The silicon-containing film is, in an example, a silicon oxide film, a silicon nitride film, a silicon carbonitride film, a polycrystalline silicon film, or a film stack including two or more of these films. The silicon-containing film may be configured by, for example, alternately stacking the silicon oxide film and the silicon nitride film. The silicon-containing film may be configured by, for example, alternately stacking the silicon oxide film and the polycrystalline silicon film. The silicon-containing film may be, for example, a film stack including the silicon nitride film, the silicon oxide film, and the polycrystalline silicon film.

In an embodiment, the etching target film EF is a carbon-containing film. The carbon-containing film is, in an example, an amorphous carbon film.

In an embodiment, the etching target film EF is a metal oxide film. The metal oxide film is, in an example, a zinc oxide film or a tin oxide film.

The mask MK has a pattern transferred to the etching target film EF by etching. The mask MK may be a single-layer mask consisting of one layer or a multi-layer mask comprising two or more layers. As illustrated in FIG. 5, a side wall SS1 of the mask MK defines at least one opening OP on the etching target film EF. The opening OP is a space on the etching target film EF and is surrounded by the side wall SS1 of the mask MK. That is, an upper surface of the etching target film EF has a region covered by the mask MK and a region exposed at a bottom portion of the opening OP.

The opening OP may have any shape in a plan view of the substrate W, that is, in a case where the substrate W is viewed in a direction from top to bottom in FIG. 5. The shape may be, for example, a circle, an ellipse, a rectangle, a line, or a shape in which one or more of these are combined. The mask MK may have a plurality of side walls, and the plurality of side walls may define a plurality of the openings OP. The plurality of openings OP may each have a linear shape and may be arranged at regular intervals to form a line & space pattern. In addition, the plurality of openings OP may each have a hole shape to form an array pattern.

The mask MK may be appropriately selected according to the etching target film EF. In an embodiment, the mask MK is formed from a material having an etching rate for the plasma formed in step ST12 or step ST3 lower than the etching rate for the plasma for the etching target film EF.

In an embodiment, the mask MK is a carbon-containing mask or a metal-containing mask. In an example, the carbon-containing mask is an amorphous carbon (ACL) film, a spin-on carbon (SOC) film, or a photoresist film. The ACL film may be doped with elements such as boron, arsenic, tungsten, and xenon. The metal-containing mask is, in an example, a metal-containing film containing the same metal as the above-described etching stop film.

Each of the underlying film UF, the etching target film EF, and the mask MK may be formed by any method. For example, the underlying film UF, the etching target film EF, and the mask MK may be formed by a CVD method, an ALD method, a PVD method, a spin coating method, or the like. The mask MK may be formed by, for example, lithography. The opening OP of the mask MK may be formed by etching the mask MK. Each of the underlying film UF, the etching target film EF, and the mask MK may be a flat film or a film having unevenness. The substrate W may further include another film under the underlying film UF. In this case, a recessed portion having a shape corresponding to the opening OP may be formed in the etching target film EF and the underlying film UF, and the other film may be used as the mask for etching.

At least a part of the process of forming the underlying film UF, the etching target film EF, and the mask MK of the substrate W may be performed in the plasma processing space 10s as a part of step ST11. For example, in a case where the opening OP of the mask MK is formed by etching, the etching in step ST11 and the etching in step ST12 may be continuously executed in the plasma processing space 10s. In an embodiment, after all or a part of the substrate W is formed by an external apparatus or a chamber of the plasma processing apparatus 1, the substrate W may be provided in the plasma processing space 10s.

In an embodiment, after the substrate W is provided in the center region 111a of the substrate support 11, the substrate support 11 is controlled to a given temperature by a temperature-controlled module. In an example, controlling the temperature of the substrate support 11 to the given temperature includes setting the temperature of the heat transfer fluid flowing in a flow passage 1110a, the temperature of the heater to the given temperature, or to a temperature different from the given temperature. Timing at which the heat transfer fluid begins to flow in the flow passage 1110a may be before, after, or at the same time as the time at which the substrate W is placed on the substrate support 11. In addition, the temperature of the substrate support 11 may be controlled to the given temperature before step ST1. That is, the substrate W may be provided to the substrate support 11 after the temperature of the substrate support 11 is controlled to the given temperature. In an embodiment, the given temperature is 0° C. or lower, −10° C. or lower, −20° C. or lower, −30° C. or lower, −40° C. or lower, −50° C. or lower, −60° C. or lower, or −70° C. or lower. In an embodiment, the given temperature is −100° C. or higher.

In an embodiment, instead of controlling the substrate support 11 to the given temperature, the substrate W may be controlled to the given temperature. Controlling the temperature of the substrate W to the given temperature includes setting the temperature of the heat transfer fluid flowing through the substrate support 11 and the flow passage 1110a and/or the temperature of the heater to the given temperature or to a temperature different from the given temperature.

In step ST12, the recessed portion is formed in the etching target film EF. First, the processing gas is supplied from the gas supply 20 into the plasma processing space 10s. The processing gas may be selected and thereby the etching target film EF can be etched with a sufficient selectivity with respect to the mask MK. The processing gas may be the same as or different from a second processing gas used in the etching of step ST3 described later.

In an embodiment, the processing gas may include a fluorine-containing gas. The fluorine-containing gas is, in an example, a hydrogen fluoride (HF) gas, a fluorocarbon gas, or a hydrofluorocarbon gas. In an embodiment, the processing gas may further include one or more gases selected from the group consisting of a phosphorus-containing gas, a carbon-containing gas, an oxygen-containing gas, a halogen-containing gas other than fluorine, and an inert gas or one or more gases selected from the group comprising a phosphorus-containing gas, a carbon-containing gas, an oxygen-containing gas, a halogen-containing gas other than fluorine, and an inert gas. The type of gas constituting the processing gas and a flow rate (partial pressure) of each gas may be constant during the processing in step ST12, or may be changed as the etching progresses.

Next, a source RF signal is supplied to the lower electrode of the substrate support 11 and/or the upper electrode of the shower head 13. As a result, an RF electric field is generated between the shower head 13 and the substrate support 11, and the plasma is formed from the processing gas in the plasma processing space 10s. In an embodiment, a bias signal may be supplied to the lower electrode of the substrate support 11. Active species such as ions and radicals in the plasma are attracted to the substrate W, and the etching target film EF is etched to form the recessed portion. The bias signal may be the bias RF signal supplied from a second RF generator 31b. The bias signal may be a bias DC signal supplied from the DC generator 32a.

In an embodiment, during the processing in step ST12, the temperature of the substrate support 11 or the substrate W may be controlled to the given temperature set in step ST11.

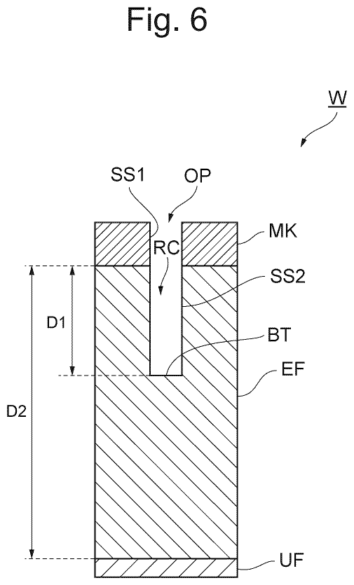

FIG. 6 is a diagram illustrating an example of the cross-sectional structure of the substrate W after processing of step ST12. As illustrated in FIG. 6, by the processing in step ST12, in the etching target film EF, the portion exposed in the opening OP is etched in a depth direction (direction from the top to the bottom in FIG. 6), and the recessed portion RC is formed. The recessed portion RC is a space defined by the side wall SS2 and the bottom portion BT of the etching target film EF.

In an embodiment, step ST12 may be ended based on dimensions (depth, opening dimensions, and aspect ratio) and/or the etching time of the recessed portion RC. In an embodiment, step ST12 may be ended at a timing before the bowing occurs in the recessed portion RC. In an embodiment, a depth D1 of the recessed portion RC after the processing of step ST12 may be 70% or less, 60% or less, 50% or less, 40% or less, 30% or less, 20% or less, 10% or less, 5% or less, 3% or less, or 1% or less of a final etching depth (for example, a depth D2 to the underlying film UF).

As described above, in step ST1, the substrate W including the etching target film EF including the recessed portion RC and the mask MK including the opening OP is prepared on the substrate support 11 of the plasma processing chamber 10. The substrate W may be prepared by forming the recessed portion RC on the substrate W by an external apparatus or a chamber of the plasma processing apparatus 1 and then providing the substrate W on the substrate support 11 of the plasma processing apparatus 1.

### Step ST2: Formation of Metal-Containing Film

In step ST2, the metal-containing film is formed on the recessed portion RC of the etching target film EF.

First, a first processing gas including the metal-containing gas is supplied from the gas supply 20 into the plasma processing space 10s. The metal-containing gas is a gas containing at least one metal (hereinafter, also referred to as a “metal M”) selected from the group consisting of ruthenium, tungsten, molybdenum, and titanium or at least one metal M selected from the group comprising ruthenium, tungsten, molybdenum, and titanium. In an embodiment, the metal-containing gas is a gas containing ruthenium and halogen. In an example, the metal-containing gas may be a RuO₃ gas, a RuO₄ gas, a RuF₅ gas, or a RuF₆ gas. In an embodiment, the metal-containing gas may be a gas containing tungsten, molybdenum, or titanium and halogen. In an example, the metal-containing gas may be a WF₂ gas, a WF₄ gas, a WFs gas, a WF₆ gas, a WCl₂ gas, a WCl₄ gas, a WCl₅ gas, a WCl₆ gas, a MoF₄ gas, a MoCl₆ gas, a TiCl₄ gas, or the like. In an embodiment, the first processing gas further includes an inert gas. The inert gas may be, for example, noble gas such as Ar gas, He gas, and Kr gas, or nitrogen gas.

Next, the source RF signal is supplied to the lower electrode of the substrate support 11 and/or the upper electrode of the shower head 13. As a result, the RF electric field is generated between the shower head 13 and the substrate support 11, and a first plasma is formed from the first processing gas in the plasma processing space 10s. In this case, the bias signal may not be supplied to the lower electrode of the substrate support 11. In addition, the bias signal may be supplied to the lower electrode of the substrate support 11. In that case, the level (power level or voltage level) of the bias signal may be lower than the level of the bias signal supplied to the substrate support 11 in step ST12 or step ST3. The bias signal may be the bias RF signal or the bias DC signal.

In an embodiment, during the processing in step ST2, the temperature of the substrate support 11 or the substrate W may be controlled to the same temperature as the given temperature set in step ST11, or may be controlled to a different temperature (for example, a temperature higher than the given temperature).

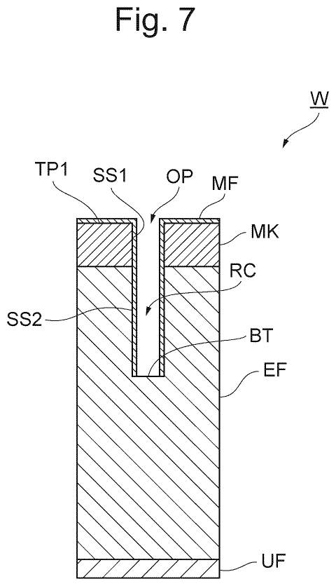

FIG. 7 is a diagram illustrating an example of the cross-sectional structure of the substrate W after processing of step ST2. As illustrated in FIG. 7, the metal-containing film MF is formed on the recessed portion RC by the processing in step ST2. The metal-containing film MF is a film containing the metal M derived from the first processing gas. In an embodiment, the metal-containing film MF is continuously formed from a top portion TP1 of the mask MK to the side wall SS1 of the mask MK and the side wall SS2 of the etching target film EF. In an embodiment, the metal-containing film MF may be formed on all of the side wall SS2 of the etching target film EF, or may be formed on a part (for example, the upper portion) of the side wall SS2. In an embodiment, the metal-containing film MF may be formed on the side wall SS2 from the upper portion of the recessed portion RC toward the bottom portion BT in a top-down manner. The metal-containing film MF may provide protection to the side wall SS2 on which the metal-containing film MF is formed, in the etching of the recessed portion RC in step ST3.

### Step ST3

In step ST3, the recessed portion RC of the etching target film EF is etched. First, a second processing gas including an HF gas is supplied from the gas supply 20 into the plasma processing space 10s.

In an embodiment, the HF gas may have the highest flow rate (partial pressure) in the second processing gas excluding the inert gas. In an example, the flow rate of the HF gas may be 50 vol % or more, 60 vol % or more, 70 vol % or more, 80 vol % or more, 90 vol % or more, or 95 vol % or more with respect to the total flow rate of the second processing gas (the flow rate of all gases excluding the inert gas in a case where the second processing gas includes the inert gas). The flow rate of the HF gas may be less than 100 vol %, 99.5 vol % or less, 98 vol % or less, or 96 vol % or less with respect to the total flow rate of the second processing gas. In an example, the flow rate of the HF gas is 70 vol % or more and 96 vol % or less with respect to the total flow rate of the second processing gas.

In an embodiment, the second processing gas further includes one or more gases selected from the group consisting of a phosphorus-containing gas, a carbon-containing gas, an oxygen-containing gas, a halogen-containing gas other than fluorine, and an inert gas or one or more gases selected from the group comprising a phosphorus-containing gas, a carbon-containing gas, an oxygen-containing gas, a halogen-containing gas other than fluorine, and an inert gas.

In an embodiment, the phosphorus-containing gas is a phosphorus halide gas. The phosphor halide gas may be, for example, a fluorinated phosphorus gas containing fluorine as a halogen element, such as PF₃ gas or PF₅ gas. In an embodiment, the phosphor halide gas may be a phosphorus chloride gas containing chlorine as the halogen element, such as PCl₃ gas or PCl₅ gas. In an embodiment, the phosphor halide gas may be a gas containing bromine or iodine as the halogen element, such as a PBr₃ gas, a PBr₅ gas, or a PI₃ gas. In an embodiment, the phosphor halide gas may be a gas containing two or more halogen elements, such as a PClF₂ gas, a PCl₂F gas, or a PCl₂F₃ gas. In an embodiment, the phosphor halide gas may be a phosphorus oxyfluoride gas or a phosphorus oxychloride gas. For example, the phosphor halide gas may be a POF₃ gas, a POCl₃ gas, a POF₂Cl₂ gas, a POFCl₂ gas, or a POF₂Cl gas. In an embodiment, the flow rate of the phosphorus-containing gas included in the second processing gas is 20 vol % or less, 10 vol % or less, or 5 vol % or less of the total flow rate of the second processing gas.

In an embodiment, the carbon-containing gas is a fluorocarbon gas and/or a hydrofluorocarbon gas. For example, the fluorocarbon gas may be at least one selected from the group consisting of CF₄ gas, C₂F₂ gas, C₂F₄ gas, C₃F₆ gas, C₃F₈ gas, C₄F₆ gas, C₄F₈ gas, and C₅F₈ gas or at least one selected from the group comprising CF₄ gas, C₂F₂ gas, C₂F₄ gas, C₃F₆ gas, C₃F₈ gas, C₄F₆ gas, C₄F₈ gas, and C₅F₈ gas. For example, the hydrofluorocarbon gas may be at least one selected from the group consisting of a CHF₃ gas, a CH₂F₂ gas, a CH₃F gas, a C₂HF₅ gas, a C₂H₂F₄ gas, a C₂H₃F₃ gas, a C₂H₄F₂ gas, a C₃HF₇ gas, a C₃H₂F₂ gas, a C₃H₂F₄ gas, a C₃H₂F₆ gas, a C₃H₃F₅ gas, a C₄H₂F₆ gas, a C₄H₅F₅ gas, a C₄H₂F₈ gas, a C₅H₂F₆ gas, a C₅H₂F₁₀ gas, and a C₅H₃F₇ gas or at least one selected from the group comprising a CHF₃ gas, a CH₂F₂ gas, a CH₃F gas, a C₂HFs gas, a C₂H₂F₄ gas, a C₂H₃F₃ gas, a C₂H₄F₂ gas, a C₃HF₇ gas, a C₃H₂F₂ gas, a C₃H₂F₄ gas, a C₃H₂F₆ gas, a C₃H₃F₅ gas, a C₄H₂F₆ gas, a C₄H₅F₅ gas, a C₄H₂F₈ gas, a C₅H₂F₆ gas, a C₅H₂F₁₀ gas, and a C₅H₃F₇ gas. In an embodiment, the carbon-containing gas is a linear gas having an unsaturated bond. As such a gas, for example, a hexafluoropropane (C₃F₆) gas, an octafluoro-1-butene, octafluoro-2-butene (C₄F₈) gas, a 1,3,3,3-tetrafluoropropene (C₃H₂F₄) gas, a trans-1,1,1,4,4,4-hexafluoro-2-butene (C₄H₂F₆) gas, a pentafluoroethyl trifluorovinyl ether (C₄F₈O) gas, a 1,2,2,2-tetrafluoroethan-1-one (CF₃COF) gas, a difluoroacetic fluoride (CHF₂COF) gas, and a carbonyl fluoride (COF₂) gas may be used.

In an embodiment, the oxygen-containing gas is, for example, at least one gas selected from the group consisting of O₂, CO, CO₂, H₂O, and H₂O₂ or at least one gas selected from the group comprising O₂, CO, CO₂, H₂O, and H₂O₂. In an example, the oxygen-containing gas is at least one gas selected from the group consisting of oxygen-containing gases other than H₂O, for example, O₂, CO, CO₂, and H₂O₂ or at least one gas selected from the group comprising oxygen-containing gases other than H₂O, for example, O₂, CO, CO₂, H₂O, and H₂O₂. The flow rate of the oxygen-containing gas may be adjusted according to the flow rate of the other gas (for example, the carbon-containing gas) included in the second processing gas.

In an embodiment, the halogen-containing gas other than fluorine may be a chlorine-containing gas, a bromine-containing gas, and/or an iodine-containing gas. The chlorine-containing gas may be, in an example, at least one gas selected from the group consisting of Cl₂, SiCl₂, SiCl₄, CCl₄, SiH₂Cl₂, Si₂Cl₆, CHCl₃, SO₂Cl₂, BCl₃, PCl₃, PCl₅, and POCl₃ or at least one gas selected from the group comprising Cl₂, SiCl₂, SiCl₄, CCl₄, SiH₂Cl₂, Si₂Cl₆, CHCl₃, SO₂Cl₂, BCl₃, PCl₃, PCl₅, and POCl₃. The bromine-containing gas may be, in an example, at least one gas selected from the group consisting of Br₂, HBr, CBr₂F₂, C₂F₅Br, PBr₃, PBr₅, POBr₃, and BBr₃ or at least one gas selected from the group comprising Br₂, HBr, CBr₂F₂, C₂F₅Br, PBr₃, PBr₅, POBr₃, and BBr₃. The iodine-containing gas may be, in an example, at least one gas selected from the group consisting of HI, CF₃I, C₂F₅I, C₃F₇I, IF₅, IF₇, I₂, and PI₃ or at least one gas selected from the group comprising HI, CF₃I, C₂F₅I, C₃F₇I, IF₅, IF₇, I₂, and PI₃. In an example, the halogen-containing gas other than fluorine may be at least one selected from the group consisting of a Cl₂ gas, a Br₂ gas, and an HBr gas or at least one selected from the group comprising Cl₂ gas, a Br₂ gas, and an HBr gas. In an example, the halogen-containing gas other than fluorine is a Cl₂ gas or an HBr gas.

In an embodiment, the inert gas is noble gas such as Ar gas, He gas, or Kr gas and/or nitrogen gas.

In an embodiment, the second processing gas may include a gas capable of generating hydrogen fluoride species (HF species) in the plasma, instead of a part or all of the HF gas. The HF species includes at least one of a gas of hydrogen fluoride, a radical, and an ion.

The gas capable of generating the HF species may be, for example, a hydrofluorocarbon gas. The hydrofluorocarbon gas may have 2 or more, 3 or more, or 4 or more carbon atoms. The hydrofluorocarbon gas is, in an example, at least one selected from the group consisting of a CH₂F₂ gas, a C₃H₂F₄ gas, a C₃H₂F₆ gas, a C₃H₃F₅ gas, a C₄H₂F₆ gas, C₄H₅F₅ gas, a C₄H₂F₈ gas, a C₅H₂F₆ gas, a C₅H₂F₁₀ gas, and a C₅H₃F₇ gas or at least one selected from the group comprising CH₂F₂ gas, a C₃H₂F₄ gas, a C₃H₂F₆ gas, a C₃H₃F₅ gas, a C₄H₂F₆ gas, C₄H₅F₅ gas, a C₄H₂F₈ gas, a C₅H₂F₆ gas, a C₅H₂F₁₀ gas, and a C₅H₃F₇ gas. The hydrofluorocarbon gas is, in an example, at least one selected from the group consisting of a CH₂F₂ gas, C₃H₂F₄ gas, a C₃H₂F₆ gas, and a C₄H₂F₆ gas or at least one selected from the group comprising CH₂F₂ gas, C₃H₂F₄ gas, a C₃H₂F₆ gas, and a C₄H₂F₆ gas.

The gas capable of generating the HF species may be, for example, a mixed gas including a hydrogen source and a fluorine source. The hydrogen source may be, for example, at least one selected from the group consisting of an H₂ gas, an NH₃gas, an H₂O gas, an H₂O₂ gas, and a hydrocarbon gas (CH₄ gas, C₃H₆ gas, and the like) or at least one selected from the group comprising H₂ gas, an NH₃gas, an H₂O gas, an H₂O₂ gas, and a hydrocarbon gas (CH₄ gas, C₃H₆ gas, and the like). The fluorine source may be, for example, a fluorine-containing gas that does not contain carbon, such as an NF₃ gas, an SF₆ gas, a WF₆ gas, or an XeF₂ gas. In addition, the fluorine source may be a fluorine-containing gas containing carbon, such as a fluorocarbon gas and a hydrofluorocarbon gas. The fluorocarbon gas may be, in an example, at least one selected from the group consisting of a CF₄ gas, a C₂F₂ gas, a C₂F₄ gas, a C₃F₆ gas, a C₃F₈ gas, a C₄F₆ gas, a C₄F₈ gas, and a C₅F₈ gas or at least one selected from the group comprising a CF₄ gas, a C₂F₂ gas, a C₂F₄ gas, a C₃F₆ gas, a C₃F₈ gas, a C₄F₆ gas, a C₄F₈ gas, and a C₅F₈ gas. The hydrofluorocarbon gas may be, in an example, at least one selected from the group consisting of a CHF₃ gas, a CH₂F₂ gas, a CH₃F gas, a C₂HF₈ gas, and a hydrofluorocarbon gas (C₃H₂F₄ gas, C₃H₂F₆ gas, C₄H₂F₆ gas, or the like) containing three or more C's or at least one selected from the group comprising a CHF₃ gas, a CH₂F₂ gas, a CH₃F gas, a C₂HF₅ gas, and a hydrofluorocarbon gas (C₃H₂F₄ gas, C₃H₂F₆ gas, C₄H₂F₆ gas, or the like) containing three or more C's.

In an embodiment, during the processing in step ST3, the type of gas constituting the second processing gas and the flow rate (partial pressure) thereof may be constant, and may be changed as the etching progresses.

Next, the source RF signal is supplied to the lower electrode of the substrate support 11 and/or the upper electrode of the shower head 13. As a result, the RF electric field is generated between the shower head 13 and the substrate support 11, and the second plasma is formed from the second processing gas in the plasma processing space 10s. In an embodiment, the bias signal may be supplied to the lower electrode of the substrate support 11. As a result, active species such as ions and radicals in the second plasma are attracted to the substrate W, and the recessed portion RC of the etching target film EF is further etched in the depth direction. The bias signal may be the bias RF signal supplied from the second RF generator 31b. The bias signal may be the bias DC signal supplied from the DC generator 32a.

In an embodiment, during the processing in step ST3, the temperature of the substrate support 11 or the substrate W may be controlled to the given temperature set in step ST11.

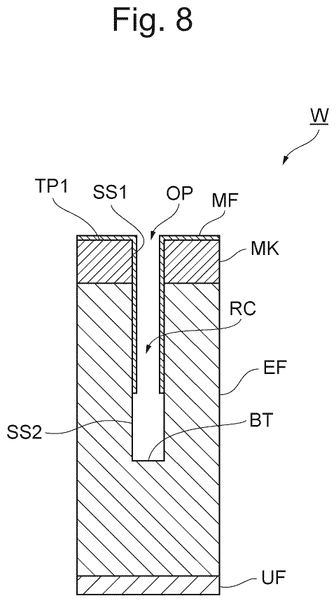

FIG. 8 is a diagram illustrating an example of the cross-sectional structure of the substrate W during processing of step ST3. As illustrated in FIG. 8, the recessed portion RC is further etched in the depth direction by the processing of step ST3. As described above, the metal-containing film MF containing the metal M (ruthenium, tungsten, molybdenum, and/or titanium) is formed on the side wall SS2 of the recessed portion RC in step ST2. The metal-containing film MF containing the metal M has low reactivity with active species of hydrogen fluoride in the second plasma. The metal-containing film MF has a higher etching resistance to the second plasma than the etching target film EF. The metal-containing film MF functions as a protective film for the side wall SS2 in the etching in step ST3. As a result, the occurrence of the bowing due to widening of the side wall SS2 of the portion where the metal-containing film is formed in the width direction (the left-right direction in FIG. 8) by etching may be suppressed. In a case where the metal-containing film MF is also formed on the mask MK, the metal-containing film MF also functions as the protective film for the mask MK. As a result, the etching selectivity of the etching target film EF with respect to the etching of the mask MK may be improved.

In a case where a given stop condition is satisfied, the etching in step ST3 is stopped, and the present method is ended. The stop condition may be, for example, an etching time or a depth of the recessed portion RC. An aspect ratio of the recessed portion RC when the etching is ended may be, for example, 20 or more, 30 or more, 40 or more, 50 or more, or 100 or more.

According to the present method, in the etching in step ST3, the occurrence of the bowing in the recessed portion RC of the etching target film EF may be suppressed. That is, the present method may suppress the occurrence of shape abnormality due to the etching.

### MODIFICATION EXAMPLES

The present method may be modified in various ways without departing from the scope and gist of the present disclosure.

In an embodiment, in the present method, step ST2 and step ST3 may be repeated. That is, step ST2 and step ST3 constitute one cycle, and the cycle may be repeated a plurality of times. In this case, the formation of the metal-containing film MF on the side wall SS2 of the recessed portion RC and the etching of the recessed portion RC in the depth direction are alternately repeated. As a result, the bowing may be further suppressed.

In an embodiment, the second processing gas used in step ST3 may further include a metal-containing gas containing the metal M. In this case, in step ST3, the formation of the metal-containing film MF on the side wall SS2 of the recessed portion RC and the etching of the recessed portion RC in the depth direction proceed at the same time. As a result, the bowing may be further suppressed.

In an embodiment, in the present method, after the execution of step ST11, step ST3 may be executed without executing step ST2, and the second processing gas used in step ST3 may include the metal-containing gas containing the metal M. In this case, in step ST3, the formation of the metal-containing film MF on the side wall SS2 of the recessed portion RC and the etching of the recessed portion RC in the depth direction proceed at the same time. As a result, the bowing may be suppressed.

In an embodiment, step ST1 may further include a step of forming the carbon-containing film on the side wall SS2 of the recessed portion RC after the recessed portion RC is formed in step ST12. The formation of the carbon-containing film may be executed, for example, by various methods such as a plasma CVD method, a thermal CVD method, or an ALD method. The metal M (ruthenium, tungsten, molybdenum, and/or titanium) tends to be easily deposited on the carbon-containing film. By forming the carbon-containing film on the side wall SS2 of the recessed portion RC in advance, the formation of the metal-containing film MF on the side wall SS2 of the recessed portion RC may be promoted in step ST2 or step ST3 according to the above-described modification example.

According to one exemplary embodiment of the present disclosure, it is possible to provide a technique for suppressing the shape abnormality of the etching.

The embodiments of the present disclosure further include the following aspects.

### Addendum 1

An etching method including:
(a) preparing a substrate, the substrate including an etching target film and a mask disposed on the etching target film, the etching target film including a recessed portion, and the mask including an opening configured to expose the recessed portion;
(b) forming a metal-containing film on a side wall of the recessed portion using a first plasma formed from a first processing gas, the first processing gas including a metal-containing gas, and the metal-containing gas including at least one metal selected from the group consisting of ruthenium, tungsten, molybdenum, and titanium; and
(c) etching the etching target film in the recessed portion using a second plasma formed from a second processing gas, the second processing gas including a hydrogen fluoride gas.

### Addendum 2

The etching method according to Addendum 1, in which the second processing gas further includes the metal-containing gas, and in the (c), the metal-containing film is formed on the side wall of the recessed portion, and the etching target film is etched in the recessed portion.

### Addendum 3

The etching method according to Addendum 1 or 2, in which a cycle including the (b) and the (c) is repeated a plurality of times.

### Addendum 4

The etching method according to any one of Addenda 1 to 3, in which the second processing gas further includes a phosphorus-containing gas.

### Addendum 5

The etching method according to any one of Addenda 1 to 4, in which in the (c), a temperature of the substrate or a substrate support configured to support the substrate is controlled to 0° C. or lower.

### Addendum 6

An etching method including:
(a) preparing a substrate, the substrate including an etching target film and a mask disposed on the etching target film, the etching target film including a recessed portion, and the mask including an opening configured to expose the recessed portion; and
(b) forming a metal-containing film on a side wall of the recessed portion using a plasma formed from a processing gas, and etching the etching target film in the recessed portion, the processing gas including a metal-containing gas and a hydrogen fluoride gas, and the metal-containing gas including at least one metal selected from the group consisting of ruthenium, tungsten, molybdenum, and titanium.

### Addendum 7

The etching method according to Addendum 6, in which the processing gas further includes a phosphorus-containing gas.

### Addendum 8

The etching method according to Addendum 6 or 7, in which in the (b), a temperature of the substrate or a substrate support configured to support the substrate is controlled to 0° C. or lower.

### Addendum 9

The etching method according to any one of Addenda 1 to 8, in which the etching target film is a silicon-containing film, a carbon-containing film, or a metal oxide film.

### Addendum 10

The etching method according to any one of Addenda 1 to 9, in which the etching target film includes at least one selected from the group consisting of a silicon oxide film, a silicon nitride film, a silicon oxynitride film, a silicon carbonitride film, a polycrystalline silicon film, and a film stack including at least two of these films.

### Addendum 11

The etching method according to any one of Addenda 1 to 10, in which the mask includes at least one metal selected from the group consisting of ruthenium, tungsten, molybdenum, titanium, indium, gallium, and zinc.

### Addendum 12

The etching method according to any one of Addenda 1 to 11, in which the mask is a carbon-containing film.

### Addendum 13

The etching method according to any one of Addenda 1 to 12, in which the substrate includes an etching stop film under the etching target film, and the etching stop film includes at least one metal selected from the group consisting of ruthenium, tungsten, molybdenum, titanium, indium, gallium, and zinc.

### Addendum 14

A plasma processing apparatus including:
a chamber; and
a controller, in which
the controller is configured to perform
   (a) a control of preparing a substrate in the chamber, the substrate including an etching target film and a mask disposed on the etching target film, the etching target film including a recessed portion, and the mask including an opening configured to expose the recessed portion,
   (b) forming of a metal-containing film on a side wall of the recessed portion using a first plasma formed from a first processing gas in the chamber, the first processing gas including a metal-containing gas, the metal-containing gas including at least one metal selected from the group consisting of ruthenium, tungsten, molybdenum, and titanium; and
   (c) etching of the etching target film in the recessed portion using a second plasma formed from a second processing gas in the chamber, the second processing gas including a hydrogen fluoride gas.

### Addendum 15

A plasma processing apparatus including:
a chamber; and
a controller, in which
the controller is configured to perform
   (a) a control of preparing a substrate, the substrate including an etching target film and a mask disposed on the etching target film, the etching target film having a recessed portion and the mask including an opening configured to expose the recessed portion, and
   (b) a control of forming a metal-containing film on a side wall of the recessed portion, and etching the etching target film in the recessed portion using a plasma formed from a processing gas including a metal-containing gas and a hydrogen fluoride gas, and the metal-containing gas including at least one metal selected from the group consisting of ruthenium, tungsten, molybdenum, and titanium.

Each of the above embodiments is described for the purpose of description, and it is not intended to limit the scope of the present disclosure. Each of the above embodiments may be modified in various ways without departing from the scope and gist of the present disclosure. For example, some configuration elements in one embodiment can be added to other embodiments. In addition, some configuration elements in one embodiment can be replaced with corresponding configuration elements in another embodiment.

What is claimed is:

1. An etching method comprising:
(a) preparing a substrate, the substrate including an etching target film and a mask disposed on the etching film, the etching target film including a recessed portion, and the mask including an opening configured to expose the recessed portion;
(b) forming a metal-containing film on a side wall of the recessed portion using a first plasma formed from a first processing gas, the first processing gas including a metal-containing gas, and the metal-containing gas including at least one metal selected from a group comprising ruthenium, tungsten, molybdenum, and titanium; and
(c) etching the etching target film in the recessed portion using a second plasma formed from a second processing gas, the second processing gas including a hydrogen fluoride gas.

2. The etching method according to claim 1, wherein the second processing gas further includes the metal-containing gas, and in the (c), the metal-containing film is formed on the side wall of the recessed portion, and the etching target film is etched in the recessed portion.

3. The etching method according to claim 1, wherein a cycle including the (b) and the (c) is repeated a plurality of times.

4. The etching method according to claim 1, wherein the second processing gas further includes a phosphorus-containing gas.

5. The etching method according to claim 1, wherein in the (c), a temperature of the substrate or a substrate support configured to support the substrate is controlled to 0° C. or lower.

6. An etching method comprising:
(a) preparing a substrate, the substrate including an etching target film and a mask disposed on the etching target film, the etching target film including a recessed portion, and the mask including an opening configured to expose the recessed portion; and
(b) forming a metal-containing film on a side wall of the recessed portion using a plasma formed from a processing gas, and etching the etching target film in the recessed portion, the processing gas including a metal-containing gas and a hydrogen fluoride gas, and the metal-containing gas including at least one metal selected from a group comprising ruthenium, tungsten, molybdenum, and titanium.

7. The etching method according to claim 6, wherein the processing gas further includes a phosphorus-containing gas.

8. The etching method according to claim 6, wherein in the (b), a temperature of the substrate or a substrate support configured to support the substrate is controlled to 0° C. or lower.

9. The etching method according to claim 1, wherein the etching target film is a silicon-containing film, a carbon-containing film, or a metal oxide film.

10. The etching method according to claim 1, wherein the etching target film includes at least one selected from the group comprising a silicon oxide film, a silicon nitride film, a silicon oxynitride film, a silicon carbonitride film, a polycrystalline silicon film, and a film stack including at least two of these films.

11. The etching method according to claim 1, wherein the mask includes at least one metal selected from the group comprising ruthenium, tungsten, molybdenum, titanium, indium, gallium, and zinc.

12. The etching method according to claim 1, wherein the mask is a carbon-containing film.

13. The etching method according to claim 1, wherein the substrate includes an etching stop film under the etching target film, and the etching stop film includes at least one metal selected from the group comprising ruthenium, tungsten, molybdenum, titanium, indium, gallium, and zinc.

14. A plasma processing apparatus comprising:
a chamber; and
control circuitry, wherein
the control circuitry is configured to perform:
(a) a control of preparing a substrate in the chamber, the substrate including an etching target film having a recessed portion and a mask disposed on the etching target film, the mask including an opening configured to expose the recessed portion,
(b) forming of a metal-containing film on a side wall of the recessed portion using a first plasma formed from a first processing gas in the chamber, the first processing gas including a metal-containing gas, the metal-containing gas including at least one metal selected from a group comprising ruthenium, tungsten, molybdenum, and titanium, and
(c) etching of the etching target film in the recessed portion using a second plasma formed from a second processing gas in the chamber, the second processing gas including a hydrogen fluoride gas.

15. The plasma processing apparatus according to claim 14, wherein the second processing gas further includes the metal-containing gas, and
in the (c), the metal-containing film is formed on the side wall of the recessed portion.

16. The plasma processing apparatus according to claim 14, wherein the control circuitry is configured to repeat a cycle including the (b) and the (c) a plurality of times.

17. The plasma processing apparatus according to claim 14, wherein the second processing gas further includes a phosphorus-containing gas.

18. The plasma processing apparatus according to claim 14, wherein in the etching, a temperature of the substrate or a substrate support configured to support the substrate is controlled to 0° C. or lower.

19. The plasma processing apparatus according to claim 14, wherein the mask is a carbon-containing film.

20. The plasma processing apparatus according to claim 14, wherein the substrate includes an etching stop film under the etching target film, and
the etching stop film includes at least one metal selected from a group comprising ruthenium, tungsten, molybdenum, titanium, indium, gallium, and zinc.
